(19) United States
(12) Patent Application Publication
(10) Pub. No.: US 2015/0087082 A1
(43) Pub. Date: Mar. 26, 2015

(54) SELECTIVE HEATING DURING SEMICONDUCTOR DEVICE PROCESSING TO COMPENSATE FOR SUBSTRATE UNIFORMITY VARIATIONS

(71) Applicant: Applied Materials, Inc., Santa Clara, CA (US)

(72) Inventor: Subramani Iyer, Fremont, CA (US)

(21) Appl. No.: 14/035,927

(22) Filed: Sep. 24, 2013

(51) Int. Cl. H01L 21/66; B23K 26/00; H01L 21/324

(52) U.S. Cl. CPC H01L 22/26; H01L 21/3247; B23K 26/0042; B23K 26/0075
USPC 438/5; 219/121.81

(57) ABSTRACT

In some embodiments, a system includes (1) a controller configured to receive information regarding substrate uniformity; (2) a processing tool configured to perform a semiconductor device manufacturing process on a substrate; and (3) a laser delivery mechanism coupled to the controller, the laser delivery mechanism configured to selectively deliver laser energy to the substrate during processing within the processing tool so as to selectively heat the substrate during processing. The controller is configured to employ the substrate uniformity information to determine a temperature profile to apply to the substrate during processing within the processing tool and to employ the laser delivery mechanism to selectively heat the substrate during processing within the processing tool based on the temperature profile. Numerous other embodiments are provided.

### FIELD

The present application relates to semiconductor device manufacturing and more particularly to selective heating during semiconductor device processing to compensate for substrate uniformity variations.

### BACKGROUND

During semiconductor device manufacturing, numerous materials are formed on and removed from a substrate to form the underlying devices. Great efforts are generally expended to produce highly uniform material layers and device features. However, distributions in material layer thickness, critical dimension (CD), and the like nonetheless exist across a substrate. As semiconductor device dimensions shrink, such variations in thickness uniformity, CD uniformity, etc., become more difficult to tolerate. As such, methods and apparatus that compensate for substrate uniformity variations are desirable.

### SUMMARY

In some embodiments, a system includes (1) a controller configured to receive information regarding substrate uniformity; (2) a processing tool configured to perform a semiconductor device manufacturing process on a substrate; and (3) a laser delivery mechanism coupled to the controller, the laser delivery mechanism configured to selectively deliver laser energy to the substrate during processing within the processing tool so as to selectively heat the substrate during processing. The controller is configured to employ the substrate uniformity information to determine a temperature profile to apply to the substrate during processing within the processing tool and to employ the laser delivery mechanism to selectively heat the substrate during processing within the processing tool based on the temperature profile.

In some embodiments, a method of selectively heating a surface of a substrate during processing includes (1) determining substrate uniformity information; (2) determining a temperature profile for a processing tool based on the substrate uniformity information; (3) loading a substrate into the processing tool; (4) processing the substrate within the processing tool; and (5) employing a laser delivery mechanism to selectively heat the substrate during processing within the processing tool based on the temperature profile. Numerous other aspects are provided.

Other features and aspects of the present invention will become more fully apparent from the following detailed description, the appended claims and the accompanying drawings.

### BRIEF DESCRIPTION OF THE FIGURES

FIG. 1 is a schematic diagram of an example system for selectively heating a substrate during processing in accordance with embodiments provided herein.

FIG. 2 is a schematic diagram of an example embodiment of the system of FIG. 1 in accordance with embodiments provided herein.

FIG. 3 is a flowchart of a method of selectively heating a substrate during semiconductor device processing to compensate for substrate uniformity variations in accordance with embodiments provided herein.

FIG. 4 illustrates an example substrate temperature profile for a substrate in accordance with some embodiments provide herein.

### DETAILED DESCRIPTION

In accordance with one or more embodiments provided herein, a laser beam is employed to selectively heat portions of a substrate during processing. For example, a laser beam may be scanned or “rastered” across a substrate while the substrate is being processed. The laser beam may be turned on and/or have a larger dwell time and/or power in areas of the substrate in which additional substrate heating is desired. In areas in which less heat is desired, the laser beam may be turned off, dwell may be decreased and/or power may be decreased.

Raising substrate temperature of an area of the substrate relative to other areas of the substrate may increase etch or deposition rates in the heated area. In some embodiments, such selective heating may be employed to compensate for substrate uniformity variations, such as variations in layer thickness or CD across the substrate. For example, a metrology tool may be employed to measure substrate uniformity information, and this information may be employed to generate a temperature profile for a substrate during processing that compensates for uniformity variations. A laser delivery mechanism may be employed to facilitate heating of the substrate according to the temperature profile.

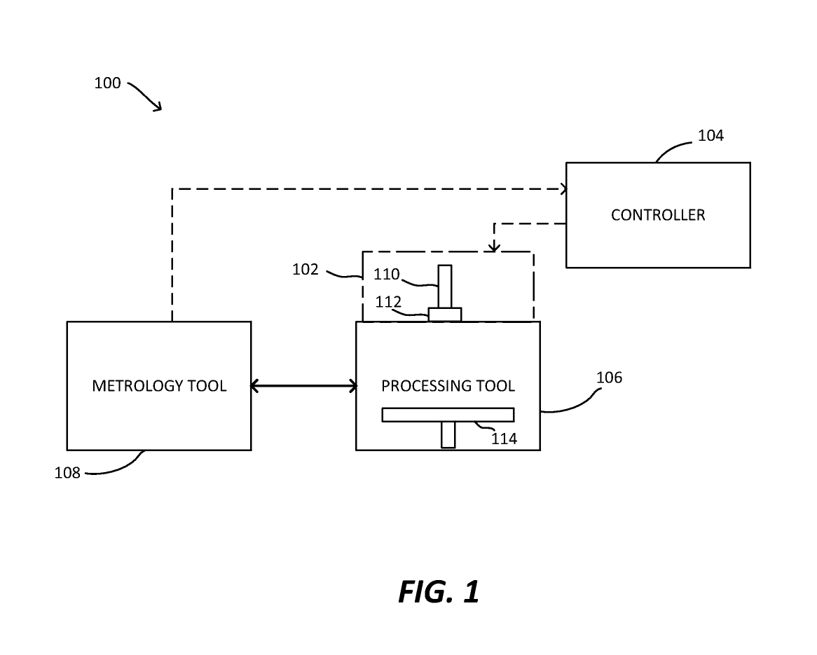

These and other embodiments of the invention are described below with reference to FIGS. 1-4.

FIG. 1 is a schematic diagram of an example system 100 for selectively heating a substrate during processing in accordance with embodiments provided herein. With reference to FIG. 1, the system 100 includes a laser delivery mechanism 102 coupled to a controller 104 and a processing tool 106. In some embodiments, a metrology tool 108 may be coupled to the controller 104 and employed to provide substrate uniformity information to the controller 104 as described below.

The laser delivery mechanism 102 may include a laser source 110 and laser beam positioning device 112. The laser source 110 may be selected based on the emission spectrum of the laser source. For example, in some embodiments, infrared wavelength light may be employed through use of a carbon dioxide laser as such wavelengths are generally absorbed by a silicon substrate. Other laser sources and/or wavelengths may be used.

The laser beam positioning device 112 may include one or more mirrors, prisms, electro-optic or acousto-optic deflectors, or the like, that may deflect or otherwise redirect a laser beam from the laser source 110 so as to cause the laser beam to scan along a portion of a substrate positioned within the processing tool 106.

The processing tool 106 may be a deposition tool, such as a chemical vapor deposition (CVD), physical vapor deposition (PVD), atomic layer deposition (ALD), or similar deposition tool, an etch tool, or any other processing tool that may benefit from selective substrate heating. In some embodiments, the processing tool 106 may include a heated substrate pedestal 114 for supporting and heating a substrate during processing within the tool 106. For example, the heated substrate pedestal 114 may provide either uniform heat across the backside of a substrate, or in some embodiments, the heated substrate pedestal 114 may have heating zones that provide different amounts of heat at different locations across the backside of a substrate (e.g., to compensate for uniformity variations in film thickness, CD, etc.). In such cases, the laser delivery mechanism 102 may be employed to provide supplemental heat to the substrate (in addition to any heat provided by the heated substrate pedestal 114). In at least some embodiments, the controller 104 may control heating by both the heated substrate pedestal 114 and the laser delivery mechanism 102.

The metrology tool 108 may be any suitable metrology tool capable of measuring film thickness uniformity, CD uniformity or any other desired substrate parameter. Example metrology tools include spectroscopic reflectometry tools, polarized spectroscopic reflectometry tools, ellipsometry tools, scanning electron microscopes, x-ray reflectometry and diffraction tools, etc. The metrology tool 108 may be a stand-alone metrology tool, or a metrology tool that is coupled to and/or integrated with the processing tool 106.

The controller 104 may a processor, such as a microprocessor, central processing unit (CPU), microcontroller or the like. The controller 104 may include computer program code and/or one or more computer program products for performing one or more of the methods described herein. Each computer program product described herein may be carried by a non-transitory medium readable by a computer (e.g., a floppy disc, a compact disc, a DVD, a hard drive, a random access memory, etc.).

In operation, a substrate is loaded into the processing tool 106 and placed on the substrate pedestal 114. The controller 104 determines a temperature profile to apply to the substrate during processing within the processing tool 106. For example, the metrology tool 108 may measure film thickness uniformity, CD uniformity and/or any other uniformity parameter relevant to the substrate which is to be processed and provide the substrate uniformity information to the controller 104. In some embodiments, the uniformity information may provide a map of thickness and/or CD variations across the substrate to be processed (or a typical substrate that has undergone similar processing). The uniformity information may identify underlying, systemic and/or inherent uniformity variations in film thickness, CD, etc., across the substrate.

Based on the substrate uniformity information, the controller 104 may create a map or temperature profile that indicates at what locations across a surface of the substrate temperature should be raised to increase etch rate or deposition rate, so as to compensate for substrate uniformity variations in thickness, CD, etc. During processing within processing tool 106, the controller 104 may direct the heated substrate pedestal 114 to heat the substrate to a desired processing temperature. In some embodiments, the heated substrate pedestal 114 may include multiple, individually controllable heating zones that the controller 104 may use to compensate for substrate uniformity variations. Alternatively, or in addition, the controller 104 may direct the laser delivery mechanism 102 to selectively heat portions of the substrate based on the temperature profile determined by the controller 104. For example, a laser beam may be scanned or “rastered” across the substrate while the substrate is being processed and turned on and/or have a larger dwell time and/or power in areas of the substrate in which additional substrate heating is desired. In areas in which less heat is desired, the laser beam may be turned off, dwell may be decreased and/or power may be decreased. As stated, raising substrate temperature of an area of the substrate relative to other areas of the substrate may increase etch or deposition rates in the heated area.

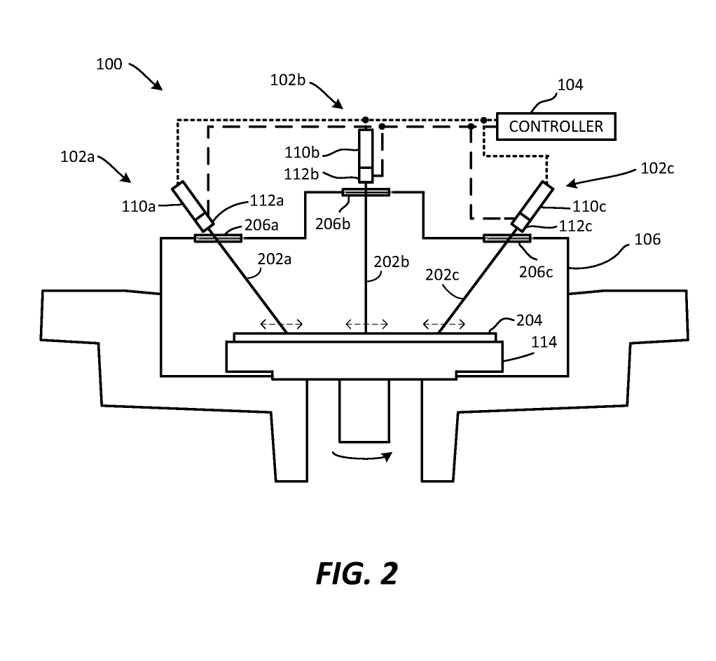

FIG. 2 is a schematic diagram of an example embodiment of the system 100 of FIG. 1 in accordance with embodiments provided herein. In the embodiment of FIG. 2, the system 100 includes a plurality of laser deliver mechanisms 102a-c, each including a laser source 110a-c and laser beam positioning device 112a-c, respectively. For example, in some embodiments, infrared wavelength light may be employed through use of a carbon dioxide laser as such wavelengths are generally absorbed by a silicon substrate. Other laser sources and/or wavelengths may be used. While three laser sources and laser beam positioning devices are shown in FIG. 2, it will be understood that fewer or more laser sources and/or laser beam positioning devices may be employed.

Each laser beam positioning device 112a-c may include one or more mirrors, prisms, electro-optic or acousto-optic deflectors, or the like, that may deflect or otherwise redirect a laser beam 202a-c from its respective laser source 110a-c so as to cause the laser beam to scan along a portion of a substrate 204 positioned within the processing tool 106. In some embodiments, the substrate 204 also may be moved relative to the laser beam (e.g., linearly, by rotation, etc.).

In one or more embodiments, the processing tool 106 may include an optical port 206a-c for each respective laser source 110a-c. For example, optical ports 206a-c may be sealed quartz windows.

Controller 104 is coupled to each laser delivery mechanism 102a-c and controls operation of the laser delivery mechanisms 102a-c. Controller 104 may be coupled to the laser delivery mechanisms 102a-c wirelessly, via wired connection, optically, etc. In some embodiments, controller 104 also may control operation of the heated substrate pedestal 114.

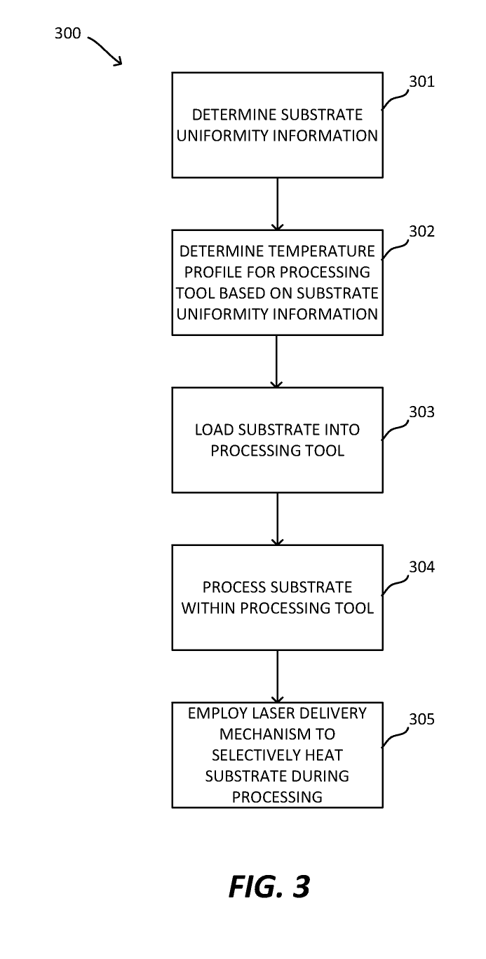

Operation of the system 100 is described below with reference to FIG. 3.

FIG. 3 is a flowchart of a method 300 of selectively heating a substrate during semiconductor device processing to compensate for substrate uniformity variations in accordance with embodiments provided herein. With reference to FIG. 3, in Block 301 substrate uniformity information is determined. For example, substrate uniformity information may be communicated to the controller 104. In some embodiments, the metrology tool 108 may measure film thickness uniformity, CD uniformity and/or any other uniformity parameter relevant to the substrate which is to be processed and provide the substrate uniformity information to the controller 104. In some embodiments, the uniformity information may provide a map of thickness and/or CD variations across the substrate to be processed (or a typical substrate that has undergone similar processing). The uniformity information may identify underlying, systemic and/or inherent uniformity variations in film thickness, CD, etc., across the substrate.

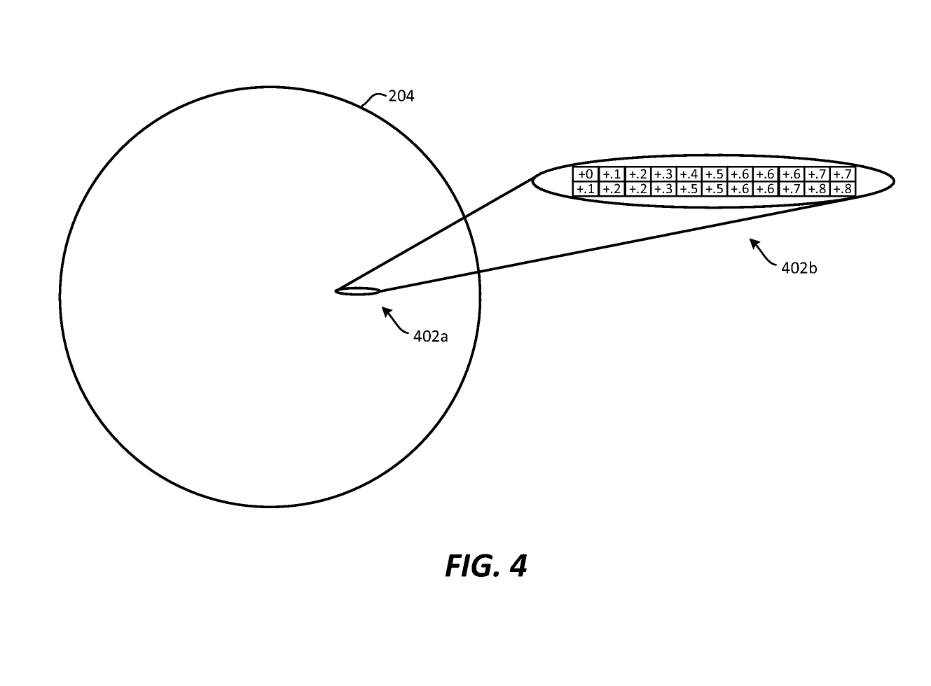

In Block 302, based on the substrate uniformity information, the controller 104 may create a map or temperature profile that indicates at what locations across a surface of the substrate temperature should be raised to increase etch rate or deposition rate, so as to compensate for substrate uniformity variations in thickness, CD, etc. For example, FIG. 4 illustrates an example substrate temperature profile for substrate 204 in accordance with some embodiments. An area or portion 402a of substrate 204 is enlarged as indicated by reference numeral 402b and provides example temperature increases in ° C. to be provided to each region of the substrate 204 within the portion 402a by one or more of laser delivery mechanisms 102a-c. The values provided in FIG. 4 are merely illustrative. Other values may be employed.

In Block 303, substrate 204 is loaded into the processing tool 106 and placed on the pedestal 114. In Block 304 the substrate 204 is processed within the processing tool 106.

During processing within processing tool 106, the controller 104 may direct the heated substrate pedestal 114 to heat the substrate 204 to a desired processing temperature. In some embodiments, the heated substrate pedestal 114 may include multiple, individually controllable heating zones that the controller 104 may use to compensate for substrate uniformity variations. Alternatively, or in addition, in Block 305 the controller 104 may direct one or more of the laser deliver mechanisms 102a-c to selectively heat portions of the substrate 204 based on the temperature profile determined by the controller 104. For example, one or more of laser beams 202a-c may be scanned or “rastered” across the substrate 204 through use of the laser beam positioning device 112a-c while the substrate 204 is being processed. The controller 104 may cause the one or more laser beams 202a-c to be turned on and/or have a larger dwell time and/or power in areas of the substrate 204 in which additional substrate heating is desired. In areas in which less heat is desired, the controller 104 may cause the one or more laser beams 202a-c to be turned off, or decrease dwell time and/or power.

Raising substrate temperature of an area of the substrate 204 relative to other areas of the substrate 204 may increase etch or deposition rates in the heated area. In some embodiments, the controller 104 may employ the laser delivery mechanisms 102a-c to selectively increase a temperature of a portion of the substrate 204 by about 1 to 2.5° C. Larger or small temperature changes may be employed.

Through use of laser heating, precise control over local temperature profile may be achieved at reaction sites during processing. This may allow highly accurate adjustments to etch or deposition rates at a local, selective level; and highly accurate compensation for substrate uniformity variations.

The foregoing description discloses only example embodiments provided herein. Modifications of the above disclosed apparatus and methods which fall within the scope of the invention will be readily apparent to those of ordinary skill in the art. For instance, other radiation sources may be employed to selectively heat a substrate such as light emitting diodes (LEDs), superluminescent LEDs (SLEDs), microwave sources, etc. In some embodiments, an electron or ion beam may be employed to selectively neutralize ions to affect etch or deposition rates (e.g., by reducing ion density of a plasma, by reducing a number of reactive species available for etch or deposition, or the like). Further, in one or more embodiments, the chip design for a substrate may be employed to affect laser heating (e.g., dwell time, power level, etc.). For example, the chip design for a substrate may provide layer type and/or thickness information across a substrate, and controller 104 may access the chip design from a database or other location and use chip design information to apply different laser dwell times, powers or the like selectively across the substrate.

Accordingly, while the present invention has been disclosed in connection with example embodiments thereof, it should be understood that other embodiments may fall within the spirit and scope of the invention, as defined by the following claims.

The invention claimed is:

1. A system comprising:
a controller configured to receive information regarding substrate uniformity;
a processing tool configured to perform a semiconductor device manufacturing process on a substrate; and
a laser delivery mechanism coupled to the controller, the laser delivery mechanism configured to selectively deliver laser energy to the substrate during processing within the processing tool so as to selectively heat the substrate during processing;
wherein the controller is configured to employ the substrate uniformity information to determine a temperature profile to apply to the substrate during processing within the processing tool and to employ the laser delivery mechanism to selectively heat the substrate during processing within the processing tool based on the temperature profile.

2. The system of claim 1 wherein the information regarding substrate uniformity includes thickness uniformity information.

3. The system of claim 1 wherein the information regarding substrate uniformity includes critical dimension (CD) uniformity information.

4. The system of claim 1 further comprising a metrology tool configured to measure substrate uniformity information and provide the substrate uniformity information to the controller.

5. The system of claim 1 wherein the substrate uniformity information is obtained by measuring a parameter of the substrate prior to processing the substrate within the processing tool.

6. The system of claim 1 wherein the processing tool is an etch tool.

7. The system of claim 1 wherein the processing tool is a deposition tool.

8. The system of claim 1 wherein the processing tool includes a heated substrate pedestal that heats the substrate during processing within the processing tool and wherein the laser delivery mechanism provides supplemental heat to the substrate during processing.

9. The system of claim 1 wherein the controller is configured to employ the laser delivery mechanism to selectively increase etch rate across a portion of the substrate based on the substrate uniformity information.

10. The system of claim 1 wherein the controller is configured to employ the laser delivery mechanism to selectively increase deposition rate across a portion of the substrate based on the substrate uniformity information.

11. The system of claim 1 wherein the controller is configured to employ the laser delivery mechanism to direct a laser beam toward a surface of the substrate and to control at least one of dwell time and power of the laser beam to selectively heat the substrate.

12. The system of claim 1 wherein the controller is configured to employ the laser delivery mechanism to selectively increase a temperature of a portion of the substrate by about 1 to 2.5° C.

13. A method of selectively heating a surface of a substrate during processing comprising:
determining substrate uniformity information;
determining a temperature profile for a processing tool based on the substrate uniformity information;
loading a substrate into the processing tool;
processing the substrate within the processing tool; and
employing a laser delivery mechanism to selectively heat the substrate during processing within the processing tool based on the temperature profile.

14. The method of claim 13 wherein the substrate uniformity information includes thickness uniformity information.

15. The method of claim 13 wherein the substrate uniformity information includes critical dimension (CD) uniformity information.

16. The method of claim 13 further comprising employing a metrology tool to measure the substrate uniformity information.

17. The method of claim 13 wherein processing the substrate includes etching the substrate.

18. The method of claim 13 wherein processing the substrate includes performing deposition on the substrate.

19. The method of claim 13 further comprising employing a heated substrate pedestal to heat the substrate during processing within the processing tool and employing the laser delivery mechanism to provide supplemental heat to the substrate during processing.

20. The method of claim 13 wherein employing the laser delivery mechanism to selectively heat the substrate during processing within the processing tool based on the temperature profile includes employing the laser delivery mechanism to selectively increase etch rate across a portion of the substrate based on the substrate uniformity information.

21. The method of claim 13 wherein employing the laser delivery mechanism to selectively heat the substrate during processing within the processing tool based on the temperature profile includes employing the laser delivery mechanism to selectively increase deposition rate across a portion of the substrate based on the substrate uniformity information.

22. The method of claim 13 wherein employing the laser delivery mechanism to selectively heat the substrate during processing within the processing tool based on the temperature profile includes controlling at least one of dwell time and power of a laser beam based on the temperature profile.

23. The method of claim 13 wherein employing the laser delivery mechanism to selectively heat the substrate during processing within the processing tool based on the temperature profile includes employing the laser delivery mechanism to selectively increase a temperature of a portion of the substrate by about 1 to 2.5° C.
